(19) United States
(12) Patent Application Publication
(10) Pub. No.: US 2009/0039331 A1
(43) Pub. Date: Feb. 12, 2009

(54) PHASE CHANGE MATERIAL STRUCTURES

(75) Inventors: Lawrence A. Clevenger, LaGrangeville, NY (US); Bruce G. Elmegreen, Goldens Bridge, NY (US); Deok-Kee Kim, Bedford Hills, NY (US); Chandrasekharan Kothandaraman, Hopewell Junction, NY (US); Lia Krusin-Elbaum, Dobbs Ferry, NY (US); Chung H. Lam, Peekskill, NY (US); Dennis M. Newns, Yorktown Heights, NY (US)

Correspondence Address: HOFFMAN WARNICK LLC, 75 STATE ST, 14TH FL, ALBANY, NY, 12207, US

(73) Assignee: INTERNATIONAL BUSINESS MACHINES CORPORATION, Armonk, NY (US)

(21) Appl. No.: 11/834,851

(22) Filed: Aug. 7, 2007

(51) Int. Cl. H01L 47/00; G11C 11/00

(52) U.S. Cl. 257/4; 257/E47.001

(57) ABSTRACT

Structures including a phase change material are disclosed. The structure may include a first electrode; a second electrode; a phase change material electrically connecting the first electrode and the second electrode for passing a current therethrough; and a tantalum nitride heater layer about the phase change material for converting the phase change material between an amorphous, insulative state and a crystalline, conductive state by application of a second current to the phase change material. The structure may be used as a fuse or a phase change material random access memory (PRAM).

### BACKGROUND

1. Technical Field

The disclosure relates generally to integrated circuit (IC) chip fabrication, and more particularly, to phase change material structures.

2. Background Art

Electronic fuses are used in IC chips to, for example, correct inoperative parts by turning on or off sections. Current electronic fuse (efuse) technology is based on techniques such as electromigration, rupture or agglomeration. These fuse technologies suffer from a number of drawbacks. For example, they are single use, take up large areas, involve quite large amounts of power/current, and are very slow, e.g., microseconds. As fuse technology develops, higher performance is desirable to, for example, reduce the area taken up by the fuse, address sun-setting of the non-standard high voltages/currents required (e.g., for electromigration fuses), provide multiple use reprogrammable fuses, and enhance speed.

Phase change material is a type of material capable of resistance changes depending on the mechanical phase of the material. Phase change material is used for phase change memory (PCM), which may also be known as ovonic unified memory (OUM), chalcogenide random access memory (CRAM) or phase-change random access memory (PRAM). Phase change material has not been used for fuse technology.

Almost all PCMs are built using a chalcogenide alloy, typically a mixture of germanium (Ge), antimony (Sb) and tellurium (Te), which is referred to as GST. One GST alloy has the formula: Ge₂Sb₂Te₅. Under high temperature (over 600° C.), a chalcogenide becomes liquid and by subsequent rapid cooling it is frozen into an amorphous glass-like state and its electrical resistance is high. By heating the chalcogenide to a temperature above its crystallization point, but below the melting point, it will transform into a crystalline state with a much lower resistance. In addition, when the material is set to a particular state representing a resistance value, the value is retained until reset by another phase change of the material. The phase switching can be completed very quickly, e.g., under 10 ns. During use as a PCM, the phase of the phase change material is typically changed by heat created by a small pulse of electrical power. Typically, this heat is provided by an internal heater, which presents reproducibility and manufacturing challenges.

### SUMMARY

Structures including a phase change material are disclosed. The structure may include a first electrode; a second electrode; a phase change material electrically connecting the first electrode and the second electrodes for passing a current therethrough; and a tantalum nitride heater layer about the phase change material for converting the phase change material between an amorphous, insulative state and a crystalline, conductive state by application of a second current to the phase change material. The structure may be used as a fuse or a phase change material random access memory (PRAM).

A first aspect of the disclosure provides a structure comprising: a first electrode; a second electrode; a phase change material electrically connecting the first electrode and the second electrode for passing a current therethrough; and a tantalum nitride heater layer about the phase change material for converting the phase change material between an amorphous, insulative state and a crystalline, conductive state by application of a second current to the phase change material.

A second aspect of the disclosure provides a structure comprising: a first copper electrode; a second copper electrode; a phase change material electrically connecting the first copper electrode and the second copper electrode for passing a first current therethrough; and a tantalum nitride heater layer about the phase change material for converting the phase change material between an amorphous, insulative state and a crystalline, conductive state by application of a second current to the phase change material; and a contact to each copper electrode, wherein the first copper electrode is positioned in one metal layer of an integrated circuit (IC) chip, and the second copper electrode is positioned in another metal layer of the IC chip.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows one embodiment of a structure according to the disclosure.

FIG. 2 shows another embodiment of a structure according to the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

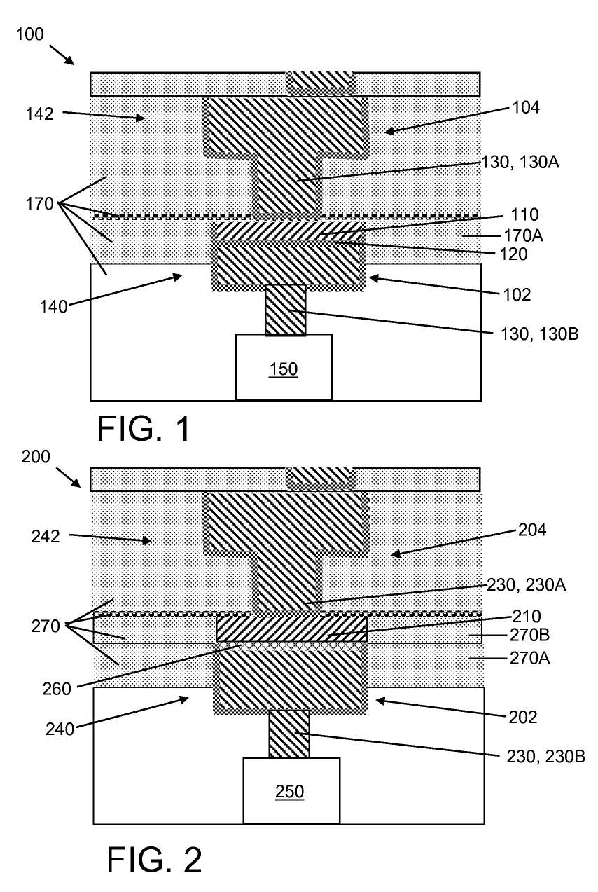

Turning to the drawings, FIGS. 1 and 2 show embodiments of a structure 100, 200 according to the disclosure. Each structure 100, 200 includes a first electrode 102, 202 and a second electrode 104, 204, respectively. In addition, each structure 100, 200 includes a phase change material 110, 210 electrically connecting first electrode 102, 202 and second electrode 104, 204. As will be described herein, phase change material 110, 210 allows for passing of a current through first and second electrodes when a sufficient current is applied. Each electrode includes at least one contact 130, 230 coupled thereto. In one embodiment, a contact 130A, 230A may be provided as part of second electrode 104, 204. First electrode 102, 202 may be positioned in a first metal layer 140, 240 of an integrated circuit (IC) chip, and second electrode may positioned in a metal layer 142, 242 above first metal layer 140, 240. In this case, contact 130B, 230B to first electrode 102, 202 may couple to a transistor 150, 250. However, other arrangements are also possible.

In FIG. 1, a tantalum nitride (TaN) heater layer 120 extends about phase change material 110 to assist in converting phase change material 110 between an amorphous, insulative state and a crystalline, conductive state by application of a sufficient current. Other refractory metal nitrides besides TaN may also be used for heater layer 120, e.g., silicon-doped TaN, titanium nitride (TiN), silicon-doped TiN, zirconium nitride (ZrN), silicon-doped ZrN, niobium nitride (NbN), silicon-doped NbN, or other refractory metal layer 120, 220 having good surface adhesive properties to adjacent material. In FIG. 2, TaN heater layer 120 is omitted. Also, in the FIG. 2 embodiment, a diffusion barrier layer 260 may be provided between first electrode 202 and phase change material 210, e.g., of a refractory metal nitride.

Structures 100, 200 are surrounded by one or more dielectric layers 170, 270 which may include but is/are not limited to: silicon nitride (Si₃N₄), silicon oxide (SiO₂), fluorinated SiO₂ (FSG), hydrogenated silicon oxycarbide (SiCOH), porous SiCOH, boro-phosho-silicate glass (BPSG), silsesquioxanes, carbon (C) doped oxides (i.e., organosilicates) that include atoms of silicon (Si), carbon (C), oxygen (0), and/or hydrogen (H), thermosetting polyarylene ethers, SiLK (a polyarylene ether available from Dow Chemical Corporation), JSR (a spin-on silicon-carbon contained polymer material available form JSR Corporation), other low dielectric constant (<3.9) material, or layers thereof.

In one embodiment, each electrode includes copper (Cu), however, other conductive materials may also be employed. Further, in one embodiment, phase change material 110, 210 may include a germanium (Ge), antimony (Sb) and tellurium (Te) alloy (commonly referred to as GST) or a germanium (Ge), antimony (Sb) and silicon (Si) alloy (GeSbSi). Other phase change materials may also be employed within the scope of the disclosure.

Structures 100, 200 may function as a fuse or a phase change random access memory (PRAM) cell. TaN heater layer 120 may obviate the need for a separate heater as is conventionally used, and allows for easier manufacturing and/or reproducibility using existing complementary metal-oxide semiconductor (CMOS) back-end-of-line (BEOL) processing technology. Sufficient additional current may be applied by applying an increased current to the two electrodes 102, 202, 104, 204, or by applying an additional current to an electrode via a second contact thereto (not shown, within page). In any event, the increased heat created by application of additional current is sufficient to convert the crystalline phase change material 110, 210 to be sufficiently amorphous 110, 210 so as to be conductive. The conversion from amorphous to crystalline does not have to be complete. In this situation, structures 100, 200 may act as multiple use, reprogrammable fuses, analogous to how PCM are used for memory applications. Structures 100, 200 may also function as a phase change random access memory (PRAM) cell. Where structures 100, 200 are used as PRAM, they will typically require a smaller cell size/higher packing density, but the operation of a single PRAM cell is the same as that of the fuse in terms of programming and sensing currents.

Structures 100, 200 may be formed using any now known or later developed CMOS BEOL processing technology. FIG. 1 shows structure 100 formed by patterning an opening in a dielectric layer 170A and then filling the opening with a conductor (e.g., liner deposition, seed layer deposition, conductor deposition and planarizing) and then phase change material 110 (e.g., tantalum nitride heater layer 160 deposition and then phase change material 110 deposition), planarizing (chemical mechanical polishing) and then forming the second metal layer 142 using conventional processes. Hence, phase change material 110 is self-aligned to first electrode 102. FIG. 2 shows structure 200 formed by patterning an opening in a dielectric layer 270A and filling the opening with a conductor and barrier diffusion layer 260, planarizing, forming another dielectric layer 270B, forming an opening, and depositing phase change material, planarizing (chemical mechanical polishing) and then forming second metal layer 242 using conventional processing. Hence, phase change material 242 may not be self-aligned to first electrode 202 in FIG. 2.

The methods and structures as described above are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The foregoing description of various aspects of the disclosure has been presented for purposes of illustration and description. It is not intended to be exhaustive or to limit the disclosure to the precise form disclosed, and obviously, many modifications and variations are possible. Such modifications and variations that may be apparent to a person skilled in the art are intended to be included within the scope of the disclosure as defined by the accompanying claims.

What is claimed is:

1. A structure comprising:
a first electrode;
a second electrode;
a phase change material electrically connecting the first electrode and the second electrode for passing a current therethrough; and
a tantalum nitride heater layer about the phase change material for converting the phase change material between an amorphous, insulative state and a crystalline, conductive state by application of a second current to the phase change material.

2. The structure of claim 1, wherein each electrode includes copper (Cu).

3. The structure of claim 1, wherein the phase change material is selected from the group consisting of: a germanium (Ge), antimony (Sb) and tellurium (Te) alloy and a germanium (Ge), antimony (Sb) and silicon (Si) alloy.

4. The structure of claim 1, wherein the first electrode is positioned in a first metal layer of an integrated circuit (IC) chip.

5. The structure of claim 4, wherein the second electrode is positioned in a metal layer above the first metal layer.

6. The structure of claim 1, wherein the structure is one of a fuse or a phase change random access memory (PRAM) cell.

7. The structure of claim 1, further comprising at least one contact to each copper electrode, the at least one contact to the first copper electrode coupled to a transistor.

8. The structure of claim 1, further comprising a diffusion barrier layer between the first electrode and the phase change material.

9. A structure comprising:
a first copper electrode;
a second copper electrode;
a phase change material electrically connecting the first copper electrode and the second copper electrode for passing a first current therethrough; and
a tantalum nitride heater layer about the phase change material for converting the phase change material between an amorphous, insulative state and a crystalline, conductive state by application of a second current to the phase change material; and
a contact to each copper electrode,
wherein the first copper electrode is positioned in one metal layer of an integrated circuit (IC) chip, and the second copper electrode is positioned in another metal layer of the IC chip.

10. The structure of claim 9, wherein the structure is one of a fuse or a phase change random access memory (PRAM) cell.

11. The structure of claim 9, further comprising the contact to the first copper electrode is coupled to a transistor.

12. The structure of claim 9, further comprising a diffusion barrier layer between the first electrode and the phase change material.
